(19) United States
(12) Patent Application Publication
(10) Pub. No.: US 2025/0111106 A1
(43) Pub. Date: Apr. 3, 2025

(54) System For Developing Geological Subsurface Models Using Machine Learning

(71) Applicant: Landmark Graphics Corporation, Houston, TX (US)

(72) Inventors: Mrigya Fogat, Bangalore (IN); Estanislao Nicolás Kozlowski, Abingdon (GB); Soumili Das, Bangalore (IN); Shreshth Srivastav, Bangalore (IN); Andrew Davies, Abingdon (GB); Geetha Nair, Houston, TX (US)

(73) Assignee: Landmark Graphics Corporation, Houston, TX (US)

(21) Appl. No.: 18/477,792

(22) Filed: Sep. 29, 2023

(51) Int. Cl. G06F 30/27

(52) U.S. Cl. CPC G06F 30/27

(57) ABSTRACT

In general, in one aspect, embodiments relate to a method that includes selecting one or more stratigraphic forward models from a digital analogue library, generating one or more k-layers based at least in part on the one or more selected stratigraphic forward models and one or more generative machine learning models, and predicting thicknesses of one or more geological properties based at least in part on the one or more k-layers.

### BACKGROUND

Subsurface geological models may be used during the planning-, exploration-, development- and/or exploitation-phases of extracting deposits of solids, liquids, and/or gases disposed in subterranean formations. In some examples, the oil and gas industry may use subsurface geological models for at least a portion of the process related to the identification and extraction of hydrocarbons including oil and gas. In some examples, the construction of subsurface geological models may include interpolation and/or extrapolation of geological properties and/or petrophysical properties collected at discreet locations which may be generalized to a 3-dimensional volume of interest. Geological properties may include properties based on one or more facies. In some examples, a facies may be a volume or region of rock with specified attributes (e.g., physical characteristics, depositional characteristics, biogenetic content, grain size, lithology, sedimentary structures, chemical characteristics, and/or formation characteristics) which may allow it to be distinguished from adjacent volumes and/or regions of rock. Petrophysical properties may include properties such as porosity, permeability, and relative permeability.

In some examples, a methodology known as stratigraphic forward modeling may be used to develop subsurface geological models based at least in part on a simulation of the geological processes. While the subsurface geological models developed by stratigraphic forward modeling may be geologically realistic, they may not always adhere to the collected observational data such as geological data gathered from previously drilled wellbores.

### BRIEF DESCRIPTION OF THE DRAWINGS

These drawings illustrate certain aspects of some examples of the present disclosure and should not be used to limit or define the disclosure.

FIG. 1 is a schematic diagram showing a seismic survey of a non-stationary environment, in accordance with one or more embodiments of the present disclosure.

FIG. 2 is a top view of the illustrative seismic survey of FIG. 1, in accordance with one or more embodiments of the present disclosure.

FIG. 3 is a schematic diagram of a drilling system, in accordance with one or more embodiments of the present disclosure.

FIG. 4 is a schematic diagram of a wireline system, in accordance with one or more embodiments of the present disclosure.

FIG. 5 is a schematic diagram of an information handling system, in accordance with one or more embodiments of the present disclosure;

FIG. 6 is a schematic diagram of an information handling system, in accordance with one or more embodiments of the present disclosure;

FIG. 7 is a schematic diagram of a network, in accordance with one or more embodiments of the present disclosure;

FIG. 8 is a schematic diagram of a neural network, in accordance with one or more embodiments of the present disclosure;

FIG. 9 is a training workflow for training one or more CGLMA algorithms to form one or more CGMLA models, in accordance with one or more embodiments of the present disclosure;

FIG. 10 is a workflow utilized to generate a digital analogue library, in accordance with one or more embodiments of the present disclosure;

FIG. 11 is a workflow for performing a layering process, in accordance with one or more embodiments of the present disclosure;

FIG. 12 is a workflow for extracting a seismic facies probability map, in accordance with one or more embodiments of the present disclosure;

FIG. 13 is a workflow for applying one or more CGLMA models to one or more datasets to form output, in accordance with one or more embodiments of the present disclosure;

FIG. 14 shows a k-layer of a chronostratigraphic section, in accordance with one or more embodiments of the present disclosure;

FIG. 15 is a schematic diagram showing thickness distribution of facies, in accordance with one or more embodiments of the present disclosure; and

FIG. 16 is a workflow for modeling a subsurface geology, in accordance with one or more embodiments of the present disclosure.

### DETAILED DESCRIPTION

This disclosure details methods and systems which utilize machine learning and deep learning algorithms as well as stratigraphic forward models (SFMs) to develop representative, geologically realistic, non-stationary subsurface geological models. The development of SFMs may be based at least in part on the “Principles of Stratigraphy” (e.g., Steno's Laws) which may include at least the law of superposition, the law of original horizontality, the law of cross-cutting relationship, and the law of lateral continuity. In examples, a SFM may be based at least in part on the principle of inclusions, the principle of unconformities, the principle of fossil succession, the principle of uniformitarianism, and the principle of catastrophism. The methods and systems detailed herein may incorporate 3-dimensional facies distribution and stratal relationships from SFM-based digital analogues with machine learning and/or deep learning algorithms to create geologically realistic models. The geologically realistic models developed may inform facies and/or their properties, one or more of their associated properties, and/or thickness distributions for a chronostratigraphic space based in part on one or more pieces of input data. In some examples, the input data may include data gathered during the construction of subterranean wellbores (e.g., from drill cuttings, mud logs, coring, etc.), data gathered from seismic surveys, well control data, etc., and any combination thereof. In some examples, the machine learning and deep learning algorithms may include one or more conditioned generative machine learning algorithms (CGMLAs), i.e., “generative machine learning models,” and in further example, a CGMLA may include one or more generative adversarial networks (GANs), which comprise both a “generator” network and a “discriminator” network.

Stratigraphy is a branch of geology focused on studying the arrangement and succession of rock layers (e.g., strata) along with the origin, composition, and depositional distribution of sediments within a rock column. In some examples, a SFM may include developing a stratigraphic model of a sedimentary basin by simulating the sedimentary and depositional processes that control the geometry and distribution of sediment deposition within a given basin or depositional area. In some examples, a library or database of previously developed SFMs may include models directed to a variety of sedimentary depositional environments. In further examples, SFMs may be grouped in accordance with the depositional environments which they represent. For example, sedimentary depositional environments may include continental environments, transitional environments, and/or marine environments. In further examples the sedimentary depositional environments may include continental environments such as aeolian, evaporitic plains, lacustrine, glacial, fluvial, delta top, mud flats, alluvial fans, and combinations thereof. In some examples, the sedimentary depositional environments may include transitional environments such as estuaries, lagoons, evaporitic plains, tidal flats, deltas (e.g., tide dominated delta, river dominated delta, and/or wave dominated delta), sabkhas, mud flats, coastal plains, coastal shelfs, reefs, barrier islands, sand bars, and combinations thereof. In some examples, the sedimentary depositional environments may include marine environments such as continental slopes, deep marine plains, submarine fans, submarine canyons, abyssal plains, and combinations thereof. The foregoing sedimentary depositional environments may result in the creation, deposition, and/or formation of, to use non-limiting examples, siliciclastic lithologies, carbonate lithologies, evaporite lithologies, organic-rich lithologies, or any combinations thereof.

The facies and lithologies created by the sedimentary depositional environments may be non-stationary, which is to say the facies do not follow a continuous trend, or that properties of closely positioned regions of the formation are less correlated than more spaced-out regions. In some examples, high energy environments may be associated with the deposition of coarse grain sediments while low energy environments may be associated with the deposition of fine grain sediments. For example, the size and/or type of sediments deposited in a particular area of a fluvial environment (e.g., river environments including but not limited to meandering rivers and braided rivers) may vary as the energy associated with the fluid in the of the river is redirected. As such, a cross section of a fluvial environment may show variations between the types of sediment deposited in the vertical direction. In other non-limiting examples, which may include marine environments, the transgression and regression of the water level (e.g., sea level) may correlate to the location in which various types of sediments are deposited in association with the energy of the environment. In further examples, some categories of transitional environments may experience higher energy than marine environments. For example, coarser grain sediments may be deposited in coastal shelf environments while smaller grain sediments may be deposited in deep marine plains and/or abyssal plains. Machine learning and deep learning algorithms trained at least in part on SFMs to able to generate non-stationary geological models representing the facies and lithologies of different depositional environments.

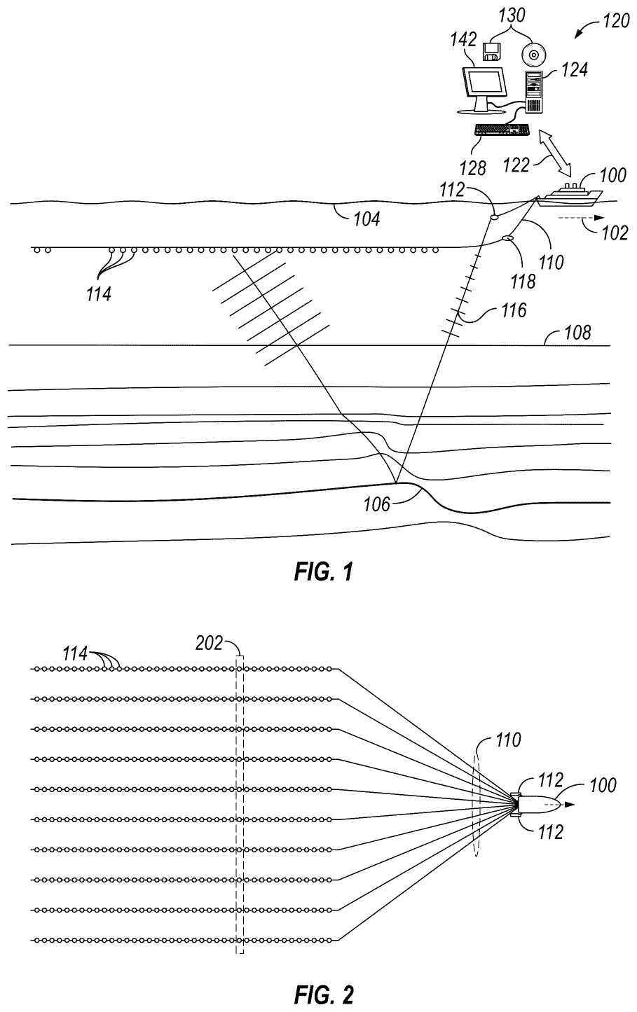

FIG. 1 illustrates a seismic survey ship 100 at sea that deploy streamers 110. Each streamer 110 trails behind the ship 100 as the ship moves forward (in the direction of arrow 102), and each streamer includes multiple evenly-spaced receivers 114. Each streamer 110 may further include a programmable diverter 118 and programmable depth controllers that pull the streamer out to an operating offset distance from the ship's path (see FIG. 2) and down to a desired operating depth (FIG. 1).

Streamers 110 may be up to several kilometers in length and constructed in 25 to 100 meter sections, where each section may include 35 (or more) receivers spaced apart in any appropriate pattern (e.g., uniformly, clustered, etc.). Each streamer 110 includes electrical or fiber-optic cabling for interconnecting receivers 114 and the seismic equipment on ship 100. Data is digitized near the receivers 114 and transmitted to the ship 100 through the cabling at rates of 7 (or more) million bits of data per second.

As shown in FIG. 1, seismic survey ship 100 may also tow one or more sources 112. Source 112 may be an impulse source or a vibratory source. FIG. 2 shows an overhead view (not to scale) of the seismic survey ship 100 towing a set of streamers 110 and two sources 112. As the ship 100 moves forward, sources 112 may be triggered alternately in a so-called flip-flop pattern. Programmable diverters are used to provide roughly even spacing between the streamers. The receivers at a given position on the streamers are associated with a common field file trace number or common channel 202. The receivers 114 used in marine seismology are commonly referred to as hydrophones, and are usually constructed using a piezoelectric transducer. Various suitable types of hydrophones are available such as disk hydrophones and cylindrical hydrophones. Sources 112 and receivers 114 typically deploy below the ocean's surface 104. Processing equipment aboard the ship controls the operation of the sources and receivers and records the acquired data.

Seismic surveys provide data for imaging below the ocean surface 104 to reveal subsurface structures such as structure 106, which lies below the ocean floor 108. Analysts employ seismic imaging methods to process the data and map the topography of the subsurface layers. Seismic survey data also reveals various other characteristics of the subsurface layers which can be used to determine the locations of oil and/or gas reservoirs.

Referring back to FIG. 1, to image the subsurface structure 106, source 112 emits seismic waves 116 that are reflected where there are changes in acoustic impedance due to subsurface structure 106 (and other subsurface reflectors). The reflected waves are detected by a pattern of receivers 114. By recording (as a function of time) the arriving seismic waves 116 that have traveled from source 112 to subsurface structure 106 to receivers 114, an image of subsurface structure 106 may be obtained after appropriate data processing. Data processing may be performed by information handling system 120. Information handling system 120 may include a personal computer 124, a video display 126, a keyboard 128 (i.e., other input devices.), and/or non-transitory computer-readable media 130 (e.g., optical disks, magnetic disks) that can store code representative of the methods described herein.

Information handling system 120 may include any instrumentality or aggregate of instrumentalities operable to compute, estimate, classify, process, transmit, receive, retrieve, originate, switch, store, display, manifest, detect, record, reproduce, handle, or utilize any form of information, intelligence, or data for business, scientific, control, or other purposes. For example, an information handling system 120 may be a personal computer, a network storage device, or any other suitable device and may vary in size, shape, performance, functionality, and price. Information handling system 120 may include random access memory (RAM), one or more processing resources such as a central processing unit (CPU) or hardware or software control logic, ROM, and/or other types of nonvolatile memory. Additional components of the information handling system 120 may include one or more disk drives 130, output devices 126, such as a video display, and one or more network ports for communication with external devices as well as an input device 128 (e.g., keyboard, mouse, etc.). Information handling system 120 may also include one or more buses operable to transmit communications between the various hardware components.

Alternatively, systems and methods of the present disclosure may be implemented, at least in part, with non-transitory computer-readable media. Non-transitory computer-readable media may include any instrumentality or aggregation of instrumentalities that may retain data and/or instructions for a period of time. Non-transitory computer-readable media may include, for example, storage media such as a direct access storage device (e.g., a hard disk drive or floppy disk drive), a sequential access storage device (e.g., a tape disk drive), compact disk, CD-ROM, DVD, RAM, ROM, electrically erasable programmable read-only memory (EEPROM), and/or flash memory; as well as communications media such wires, optical fibers, microwaves, radio waves, and other electromagnetic and/or optical carriers; and/or any combination of the foregoing. Processing methods and systems, discussed below, may also be utilized for stationary environments.

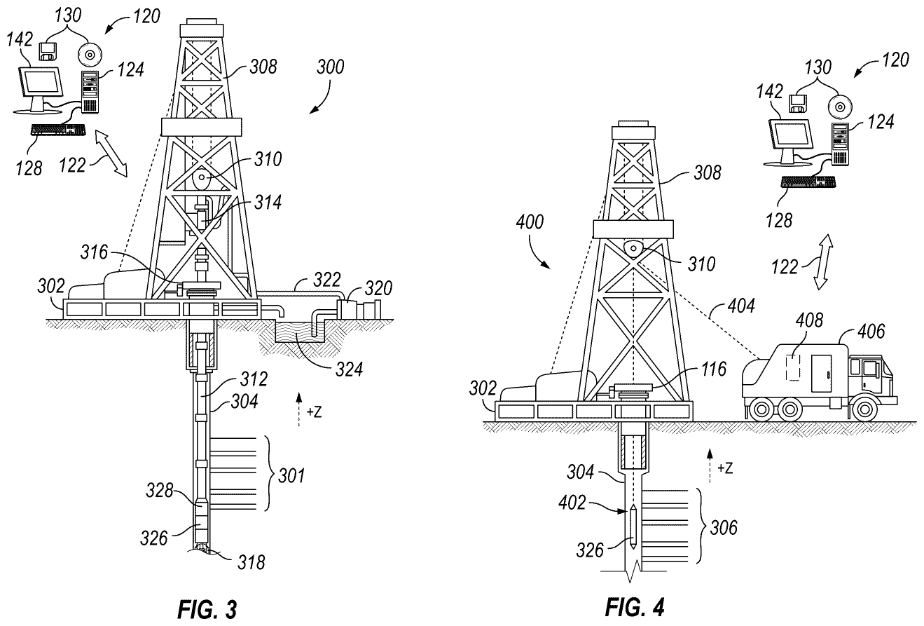

FIG. 3 is a schematic diagram of drilling system 300 that may employ the principles of the present disclosure in a stationary environment. As illustrated, drilling system 300 may include a drilling platform 302 positioned at the surface and a wellbore 304 that extends from the drilling platform 302 into one or more subterranean formations 306. In other embodiments, such as in an offshore drilling operation, a volume of water may separate the drilling platform 302 and the wellbore 304.

Drilling system 300 may include a derrick 308 supported by the drilling platform 302 and having a traveling block 310 for raising and lowering a drill string 312. A kelly 314 may support the drill string 312 as it is lowered through a rotary table 316. A drill bit 318 may be coupled to the drill string 312 and driven by a downhole motor and/or by rotation of the drill string 312 by the rotary table 316. As drill bit 318 rotates, it creates the wellbore 304, which penetrates the subterranean formations 306. A pump 320 may circulate drilling fluid through a feed pipe 322 and the kelly 314, downhole through the interior of drill string 312, through orifices in the drill bit 318, back to the surface via the annulus defined around drill string 312, and into a retention pit 324. The drilling fluid cools drill bit 318 during operation and transports cuttings from the wellbore 304 into retention pit 324.

Drilling system 300 may further include a bottom hole assembly (BHA) coupled to the drill string 312 near the drill bit 318. The BHA may comprise various downhole measurement tools such as, but not limited to, measurement-while-drilling (MWD) and logging-while-drilling (LWD) tools, which may be configured to take downhole measurements of drilling conditions. The MWD and LWD tools may include at least one wellbore logging tool 326, which may comprise one or more antennas capable of receiving and/or transmitting one or more electromagnetic (EM) signals that are axially spaced along the length of the wellbore logging tool 126.

As drill bit 318 extends wellbore 304 through formations 306, the wellbore logging tool 326 may continuously or intermittently collect azimuthally-sensitive measurements relating to the resistivity of the formations 306, i.e., how strongly the formations 306 opposes a flow of electric current. Wellbore logging tool 326 and other sensors of the MWD and LWD tools may be communicably coupled to a telemetry module 328 used to transfer measurements and signals from the BHA to a surface receiver (not shown) and/or to receive commands from the surface receiver. The telemetry module 328 may encompass any known means of downhole communication including, but not limited to, a mud pulse telemetry system, an acoustic telemetry system, a wired communications system, a wireless communications system, or any combination thereof. In certain embodiments, some or all of the measurements taken at the wellbore logging tool 326 may also be stored within the wellbore logging tool 326 or the telemetry module 328 for later retrieval at the surface upon retracting the drill string 312.

At various times during the drilling process, drill string 312 may be removed from wellbore 304, as shown in FIG. 4, to conduct measurement/logging operations. More particularly, FIG. 4 depicts a schematic diagram of an exemplary wireline system 400 that may employ the principles of the present disclosure in a stationary environment. Like numerals used in FIGS. 3 and 4 refer to the same components or elements and, therefore, may not be described again in detail. As illustrated, the wireline system 400 may include a wireline instrument sonde 402 that may be suspended into the wellbore 304 by a cable 404. The sonde is the portion of the logging tool that contains the measurement sensors. The wireline instrument sonde 402 and the wellbore logging tool 326 described above, which may be communicably coupled to the cable 404. The cable 404 may include conductors for transporting power to the wireline instrument sonde 402 and also facilitate communication between the surface and the wireline instrument sonde 402. A logging facility 406, shown in FIG. 4 as a truck, may collect measurements from the wellbore logging tool 326, and may include computing and data acquisition systems 408 for controlling, processing, storing, and/or visualizing the measurements gathered by the wellbore logging tool 326. The computing and data acquisition systems 408 may be communicably coupled to the wellbore logging tool 326 by way of the cable 404.

With continue reference to FIGS. 3 &4, the BHA, as well as wireline instrument sonde 402 may be connected to and/or controlled by information handling system 120, which may be disposed on surface. In examples, information handling system 120 may be disposed downhole in the BHA or wireline instrument sonde 402. Further, an information handling system 120 may be disposed at the surface and operate with a downhole information handling system disposed downhole on the BHA or wireline instrument sonde 402. In addition to the sensors and measurement devices disposed on the BHA or wireline instrument sonde 402, information handling system 120 may be connected to sensors disposed on any other piece of equipment used in drilling system 300 or wireline system 400. Processing of information recorded may occur down hole and/or on surface. Processing occurring downhole may be transmitted to surface to be recorded, observed, and/or further analyzed. Additionally, information recorded on information handling system 120 that may be disposed down hole may be stored until the BHA or wireline instrument sonde 402 may be brought to surface 108. In examples, information handling system 120 may communicate with the BHA or wireline instrument sonde 402 through a communication line (not illustrated) disposed in (or on) drill string. In examples, wireless communication may be used to transmit information back and forth between information handling system 120 and the BHA or wireline instrument sonde 402. Information handling system 120 may transmit information to the BHA or wireline instrument sonde 402 and may receive as well as process information recorded by the BHA or wireline instrument sonde 402. In examples, a downhole information handling system (not illustrated) may include, without limitation, a microprocessor or other suitable circuitry, for estimating, receiving, and processing signals from the BHA or wireline instrument sonde 402. Downhole information handling system (not illustrated) may further include additional components, such as memory, input/output devices, interfaces, and the like. In examples, while not illustrated, the BHA or wireline instrument sonde 402 may include one or more additional components, such as analog-to-digital converter, filter, and amplifier, among others, that may be used to process the measurements of the BHA or wireline instrument sonde 402 before they may be transmitted to surface. Alternatively, raw measurements from the BHA or wireline instrument sonde 402 may be transmitted to surface.

Any suitable technique for communication link 122 may be used for transmitting signals from the BHA or wireline instrument sonde 402 to surface, including, but not limited to, wired pipe telemetry, mud-pulse telemetry, acoustic telemetry, and electromagnetic telemetry. While not illustrated, the BHA may include a telemetry subassembly that may transmit telemetry data to surface. At surface, pressure sensors (not shown) may convert the pressure signal into electrical signals for a digitizer (not illustrated). The digitizer may supply a digital form of the telemetry signals to information handling system 120 via a communication link 122, which may be a wired or wireless link. The telemetry data may be analyzed and processed by information handling system 120. Information handling system 120 may analyze and process data based at least in part on different systems that work together to form information handling system 120.

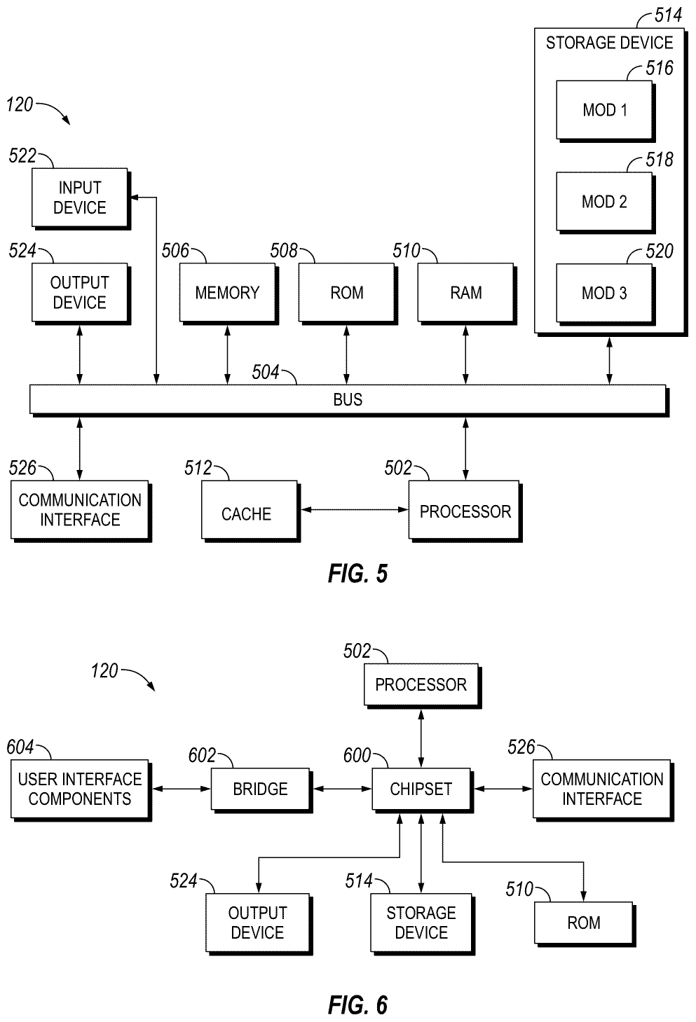

FIG. 5 illustrates an example information handling system 120 which may be employed to perform various steps, methods, and techniques disclosed herein. Persons of ordinary skill in the art will readily appreciate that other system examples are possible. As illustrated, information handling system 120 includes a processing unit (CPU or processor) 502 and a system bus 504 that couples various system components including system memory 506 such as read only memory (ROM) 508 and random-access memory (RAM) 210 to processor 502. Processors disclosed herein may all be forms of this processor 502. Information handling system 120 may include a cache 512 of high-speed memory connected directly with, in close proximity to, or integrated as part of processor 502. Information handling system 120 copies data from memory 506 and/or storage device 514 to cache 512 for quick access by processor 502. In this way, cache 512 provides a performance boost that avoids processor 502 delays while waiting for data. These and other modules may control or be configured to control processor 502 to perform various operations or actions. Other system memory 506 may be available for use as well. Memory 506 may include multiple different types of memory with different performance characteristics. It may be appreciated that the disclosure may operate on information handling system 120 with more than one processor 502 or on a group or cluster of computing devices networked together to provide greater processing capability. Processor 502 may include any general-purpose processor and a hardware module or software module, such as first module 516, second module 518, and third module 520 stored in storage device 514, configured to control processor 502 as well as a special-purpose processor where software instructions are incorporated into processor 502. Processor 502 may be a self-contained computing system, containing multiple cores or processors, a bus, memory controller, cache, etc. A multi-core processor may be symmetric or asymmetric. Processor 502 may include multiple processors, such as a system having multiple, physically separate processors in different sockets, or a system having multiple processor cores on a single physical chip. Similarly, processor 502 may include multiple distributed processors located in multiple separate computing devices but working together such as via a communications network. Multiple processors or processor cores may share resources such as memory 506 or cache 512 or may operate using independent resources. Processor 502 may include one or more state machines, an application specific integrated circuit (ASIC), or a programmable gate array (PGA) including a field PGA (FPGA).

Each individual component discussed above may be coupled to system bus 504, which may connect each and every individual component to each other. System bus 504 may be any of several types of bus structures including a memory bus or memory controller, a peripheral bus, and a local bus using any of a variety of bus architectures. A basic input/output (BIOS) stored in ROM 508 or the like, may provide the basic routine that helps to transfer information between elements within information handling system 120, such as during start-up. Information handling system 120 further includes storage devices 514 or computer-readable storage media such as a hard disk drive, a magnetic disk drive, an optical disk drive, tape drive, solid-state drive, RAM drive, removable storage devices, a redundant array of inexpensive disks (RAID), hybrid storage device, or the like. Storage device 514 may include software modules 516, 518, and 520 for controlling processor 502. Information handling system 120 may include other hardware or software modules. Storage device 514 is connected to the system bus 504 by a drive interface. The drives and the associated computer-readable storage devices provide nonvolatile storage of computer-readable instructions, data structures, program modules and other data for information handling system 120. In one aspect, a hardware module that performs a particular function includes the software component stored in a tangible computer-readable storage device in connection with the necessary hardware components, such as processor 502, system bus 504, and so forth, to carry out a particular function. In another aspect, the system may use a processor and computer-readable storage device to store instructions which, when executed by the processor, cause the processor to perform operations, a method or other specific actions. For example, the hybrid data generator, which may include a Large Language Model or other models derived from machine learning- and deep learning algorithms, may include computational instructions which may be executed on a processor to generate an initial and/or an updated geological model. In some examples, the deep learning algorithms may include convolutional neural networks, long short term memory networks, recurrent neural networks, generative adversarial networks, attention neural networks, zero-shot models, fine-tuned models, domain-specific models, multi-modal models, transformer architectures, radial basis function networks, multilayer perceptrons, self-organizing maps, deep belief networks, and combinations thereof. The basic components and appropriate variations may be modified depending on the type of device, such as whether information handling system 120 is a small, handheld computing device, a desktop computer, or a computer server. When processor 502 executes instructions to perform “operations”, processor 502 may perform the operations directly and/or facilitate, direct, or cooperate with another device or component to perform the operations.

As illustrated, information handling system 120 employs storage device 514, which may be a hard disk or other types of computer-readable storage devices which may store data that are accessible by a computer, such as magnetic cassettes, flash memory cards, digital versatile disks (DVDs), cartridges, random access memories (RAMs) 510, read only memory (ROM) 508, a cable containing a bit stream and the like, may also be used in the exemplary operating environment. Tangible computer-readable storage media, computer-readable storage devices, or computer-readable memory devices, expressly exclude media such as transitory waves, energy, carrier signals, electromagnetic waves, and signals per se.

To enable user interaction with information handling system 120, an input device 522 represents any number of input mechanisms, such as a microphone for speech, a touch-sensitive screen for gesture or graphical input, keyboard, mouse, motion input, speech and so forth. An output device 524 may also be one or more of a number of output mechanisms known to those of skill in the art. In some instances, multimodal systems enable a user to provide multiple types of input to communicate with information handling system 120. Communications interface 526 generally governs and manages the user input and system output. There is no restriction on operating on any particular hardware arrangement and therefore the basic hardware depicted may easily be substituted for improved hardware or firmware arrangements as they are developed.

As illustrated, each individual component describe above is depicted and disclosed as individual functional blocks. The functions these blocks represent may be provided through the use of either shared or dedicated hardware, including, but not limited to, hardware capable of executing software and hardware, such as a processor 502, that is purpose-built to operate as an equivalent to software executing on a general-purpose processor. For example, the functions of one or more processors presented in FIG. 5 may be provided by a single shared processor or multiple processors. (Use of the term “processor” should not be construed to refer exclusively to hardware capable of executing software.) Illustrative examples may include microprocessor and/or digital signal processor (DSP) hardware, read-only memory (ROM) 508 for storing software performing the operations described below, and random-access memory (RAM) 510 for storing results. Very large-scale integration (VLSI) hardware examples, as well as custom VLSI circuitry in combination with a general-purpose DSP circuit, may also be provided.

FIG. 6 illustrates an example information handling system 120 having a chipset architecture that may be used in executing the described method and generating and displaying a graphical user interface (GUI). Information handling system 120 is an example of computer hardware, software, and firmware that may be used to implement the disclosed technology. Information handling system 120 may include a processor 502, representative of any number of physically and/or logically distinct resources capable of executing software, firmware, and hardware configured to perform identified computations. Processor 502 may communicate with a chipset 300 that may control input to and output from processor 502. In this example, chipset 600 outputs information to output device 524, such as a display, and may read and write information to storage device 514, which may include, for example, magnetic media, and solid-state media. Chipset 600 may also read data from and write data to RAM 510. A bridge 602 for interfacing with a variety of user interface components 304 may be provided for interfacing with chipset 600. Such user interface components 604 may include a keyboard, a microphone, touch detection and processing circuitry, a pointing device, such as a mouse, and so on. In general, inputs to information handling system 120 may come from any of a variety of sources including machine generated and/or human generated.

Chipset 600 may also interface with one or more communication interfaces 526 that may have different physical interfaces. Such communication interfaces may include interfaces for wired and wireless local area networks, for broadband wireless networks, as well as personal area networks. Some applications of the methods for generating, displaying, and using the GUI disclosed herein may include receiving ordered datasets over the physical interface or be generated by the machine itself by processor 502 analyzing data stored in storage device 514 or RAM 510. Further, information handling system 120 may receive one or more inputs from a user via user interface components 604 and execute appropriate functions, such as browsing functions by interpreting these inputs using processor 502.

In examples, information handling system 120 may also include tangible and/or non-transitory computer-readable storage devices for carrying or having computer-executable instructions or data structures stored thereon. Such tangible computer-readable storage devices may be any available device that may be accessed by a general purpose or special purpose computer, including the functional design of any special purpose processor as described above. By way of example, and not limitation, such tangible computer-readable devices may include RAM, ROM, EEPROM, CD-ROM or other optical disk storage, magnetic disk storage or other magnetic storage devices, or any other device which may be used to carry or store desired program code in the form of computer-executable instructions, data structures, or processor chip design. When information or instructions are provided via a network, or another communications connection (either hardwired, wireless, or combination thereof), to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

In additional examples, methods may be practiced in network computing environments with many types of computer system configurations, including personal computers, hand-held devices, multi-processor systems, microprocessor-based or programmable consumer electronics, network PCs, minicomputers, mainframe computers, and the like. Examples may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

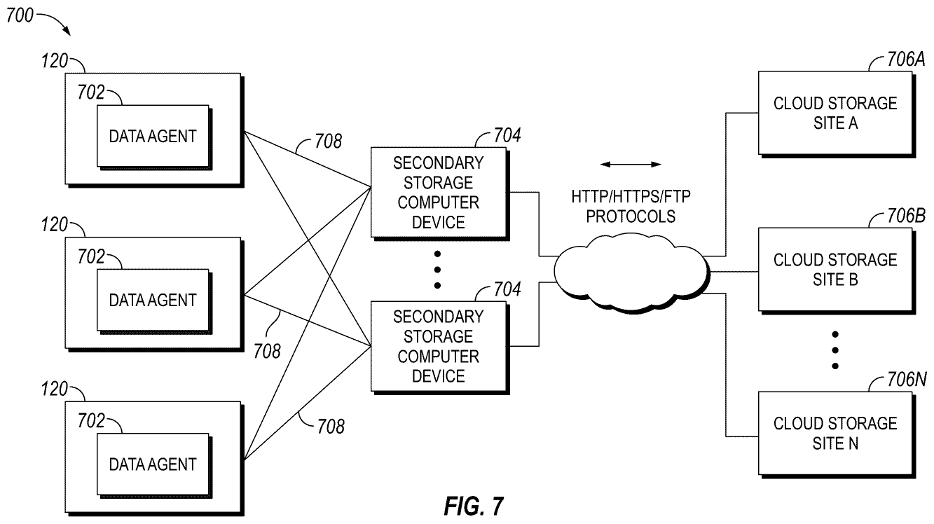

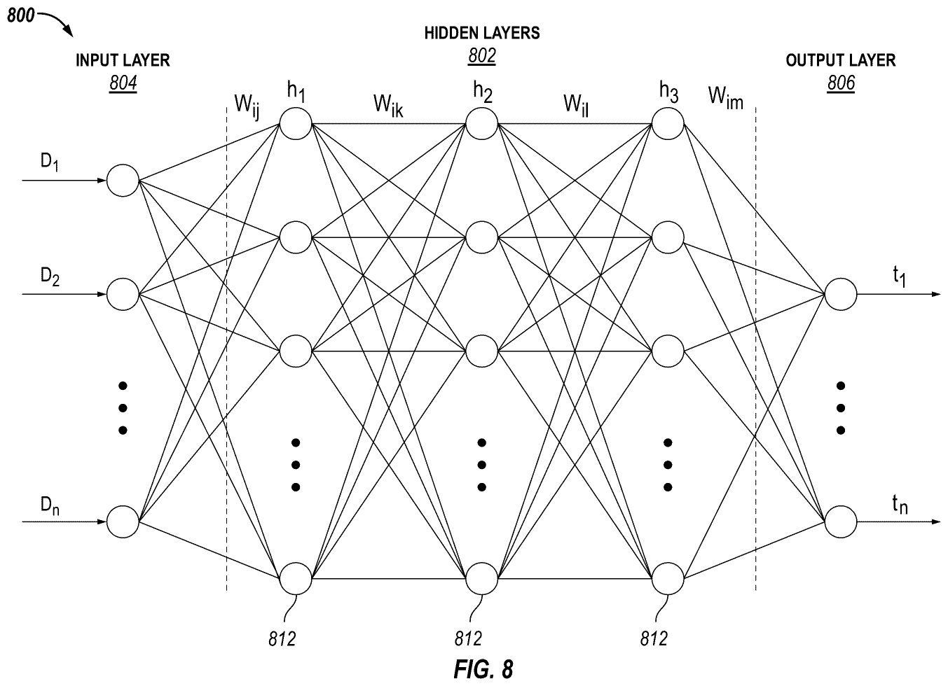

FIG. 7 illustrates an example of one arrangement of resources in a computing network 700 that may employ the processes and techniques described herein, although many others are of course possible. As noted above, an information handling system 120, as part of their function, may utilize data, which includes files, directories, metadata (e.g., access control list (ACLS) creation/edit dates associated with the data, etc.), and other data objects. The data on the information handling system 120 is typically a primary copy (e.g., a production copy). During a copy, backup, archive or other storage operation, information handling system 120 may send a copy of some data objects (or some components thereof) to a secondary storage computing device 704 by utilizing one or more data agents 702.

A data agent 702 may be a desktop application, website application, or any software-based application that is run on information handling system 120. As illustrated, information handling system 120 may be disposed at any rig site (e.g., referring to FIG. 1) or repair and manufacturing center. The data agent may communicate with a secondary storage computing device 704 using communication protocol 708 in a wired or wireless system. The communication protocol 708 may function and operate as an input to a website application. In the website application, field data related to pre- and post-operations, generated DTCs, notes, and the like may be uploaded. Additionally, information handling system 120 may utilize communication protocol 708 to access processed measurements, operations with similar DTCs, troubleshooting findings, historical run data, and/or the like. This information is accessed from secondary storage computing device 704 by data agent 702, which is loaded on information handling system 120.

Secondary storage computing device 704 may operate and function to create secondary copies of primary data objects (or some components thereof) in various cloud storage sites 706A-N. Additionally, secondary storage computing device 704 may run determinative algorithms on data uploaded from one or more information handling systems 120, discussed further below. Communications between the secondary storage computing devices 704 and cloud storage sites 706A-N may utilize REST protocols (Representational state transfer interfaces) that satisfy basic C/R/U/D semantics (Create/Read/Update/Delete semantics), or other hypertext transfer protocol (“HTTP”)-based or file-transfer protocol (“FTP”)-based protocols (e.g., Simple Object Access Protocol).

In conjunction with creating secondary copies in cloud storage sites 706A-N, the secondary storage computing device 704 may also perform local content indexing and/or local object-level, sub-object-level or block-level deduplication when performing storage operations involving various cloud storage sites 706A-N. Cloud storage sites 706A-N may further record and maintain DTC code logs for each downhole operation or run, map DTC codes, store repair and maintenance data, store operational data, and/or provide outputs from determinative algorithms and or models that are located in cloud storage sites 706A-N. In a non-limiting example, this type of network may be utilized as a platform to store, backup, analyze, import, and perform extract, transform and load (“ETL”) processes to the data gathered during a drilling operation. In further examples, this type of network may be utilized in a neural network environment.

FIG. 8 illustrates a neural network 800 that may be utilized to draw a relationship between independent and dependent variables, or to identify relationships within a set of exclusively independent variables as described herein. Neural network 800 may be an artificial neural network with one or more hidden layers 802 between input layer 804 and output layer 806. As illustrated, input layer 804 may include multi-disciplinary datasets as described in the foregoing, whereas output layers 806 may include data which may further feed the model stack, or may provide outputs used to populate a geological model. As such, the outputs from neural network 800 may provide results which are directly included in the geological model, or may function as inputs to a subsequent model or series of models which may then provide results which may be included in the geological model. Input data is provided to neurons 812 in first layer, the output of those neurons 812 is then provided as inputs to neurons 812 in the next layer. That is, the outputs of each neuron 812 are subsequently passed as inputs to successive neurons 812 (in the next hidden layer 802), until one or more final output(s) are produced by neurons 812 in output layer 806. Each layer may have one or more neurons 812. The connection between two neurons 812 of successive layers may have an associated weight. The weight defines the influence of the input to the output for the next neuron 812 and eventually for the overall final output. As will be discussed in detail below, neural network 800, that may be utilized in a computing network 700 (e.g., referring to FIG. 7), may be utilized for geological modeling.

As alluded to previously, rendering subsurface geological models, e.g., reservoir, static or geo-cellular models, may utilize interpolation/extrapolation of geological and/or petrophysical properties from discrete locations to one or more three-dimensional volumes of interest. Various geostatistical methods, such as kriging, sequential indicator or sequential gaussian simulation may fail to capture the inherent non-stationarity nature in geology, resulting in implausible geological models. Other methods, such as object-based modelling or multi-point statistics, may allow for more accurate models to be generated, however, such models may be difficult to implement, prone to bias, and/or are only valid based on the correctness of the parameters provided by the user. Although four-dimensional (4D) stratigraphic forward models (SFMs) produce more geologically realistic models, these models require expertise to implement and often fail to adhere to observational (or conditioning) data. Discussed below are methods and systems that utilize one or more SFMs, geological process-based models, hybrid models, process-mimicking models, or any combination thereof, to train machine learning based models to generate non-stationary, geologically realistic models that adhere to conditioning data. Existing workflows for generating three-dimensional subsurface models based on directly predicting properties in three-dimensional space using Deep Learning algorithms fail to be practical since they require relative larger training data sets than the ones required to predict properties in 2D, are more difficult to condition, and lack the flexibility of output often required to be applicable.

Methods and systems discussed below may be utilized to generate more geologically realistic models. Specifically, this may be performed by transferring three-dimensional facies distribution and stratal relationships from SFM-based digital analogues to the subsurface domain, using conditioned generative machine learning algorithms (CGMLAs). Training the CGMLAs may be performed using geological data in relative chronostratigraphic space to obtain predictive outputs of geological property/ies and thickness distributions. Input training data may comprise single or multiple pairs of thickness and geological property data points (e.g., such as facies, grain size, proportion of different lithologies, porosity, permeability), secondary spatial trend maps (e.g., from seismic), and/or associated parameters, including geological, physical, or mathematical parameters generated during construction of the digital analogues, or extracted from the digital analogue (e.g., net to gross).

As used herein, “digital analogues” or “analogue models” refer to the SFM-based digital analogues mentioned above. Digital analogues are digital representations of SFM used to replicate, simulate, or otherwise represent the behavior and characteristics of SFM. Digital analogues possess many of the advantages of SFM while being more versatile, easier to manipulate, and may be more computationally efficient to use than the actual SFM in some examples. Digital analogues may in some examples replicate the essence and behavior of SFM, providing analysis and visualization associated therewith, without requiring to re-run the entire SFM each time the digital analogue is called in a program.

Predictions are generated by some of the models described herein. Predictions are outputs of models and which may, in some examples, be later used to represent real-world characteristics. For example, predictions may correspond to or be otherwise based on an identified stratigraphic level (with geological property/ies and/or thickness information) in well and/or seismic data used for the CGMLAs conditioning. Although predictions from the CGMLAs may be sufficient to produce a vertically homogenous three-dimensional representation of facies distribution (since a facies and property/ies map pair is generated), the workflow may be expanded by generating multiple predictions of thickness and facies pairs of vertically continuous chronostratigraphic levels and stacking them together to form a vertically heterogenous model. In one or more examples, predictions may comprise or be based on a generative output, e.g., from one or more GANs, and may be guided by one or more constraints or boundaries input into one or more models.

Following the laws of nature, where resulting deposition, e.g., of sedimentary layers, is a result of pre-existing conditions, methods and systems discussed below propose a bottom-up (or older to younger) approach to generating and vertically stacking multiple predictions. “Stacking” as used herein refers to compiling two-dimensional renderings to form a vertically homogenous or three- or four-dimensional model. Previous (underlaying) predictions are used, directly or indirectly, to condition the current prediction, to produce three-dimensional stratal architectures that are equivalent to the SFM digital analogues. Data located above the level of interest (such as property/thickness pairs from wells overlying the facies/property pairs used to condition the prediction) may also be used to condition the prediction. (A “property” may comprise thickness). This approach allows to circumvent the issues of training a generative model directly from a three-dimensional volume of properties, while also having a greater flexibility on the outcomes. Thus, the methods and systems described below may generate more geologically realistic models by focusing on transferring three-dimensional facies distribution and stratal relationships from SFM-based digital analogues to the subsurface domain. Utilizing an SFM or SFM-based digital analogue to train and/or guide predictions of a CGMLA may allow for creating one or more geologically realistic three- or four-dimensional models.

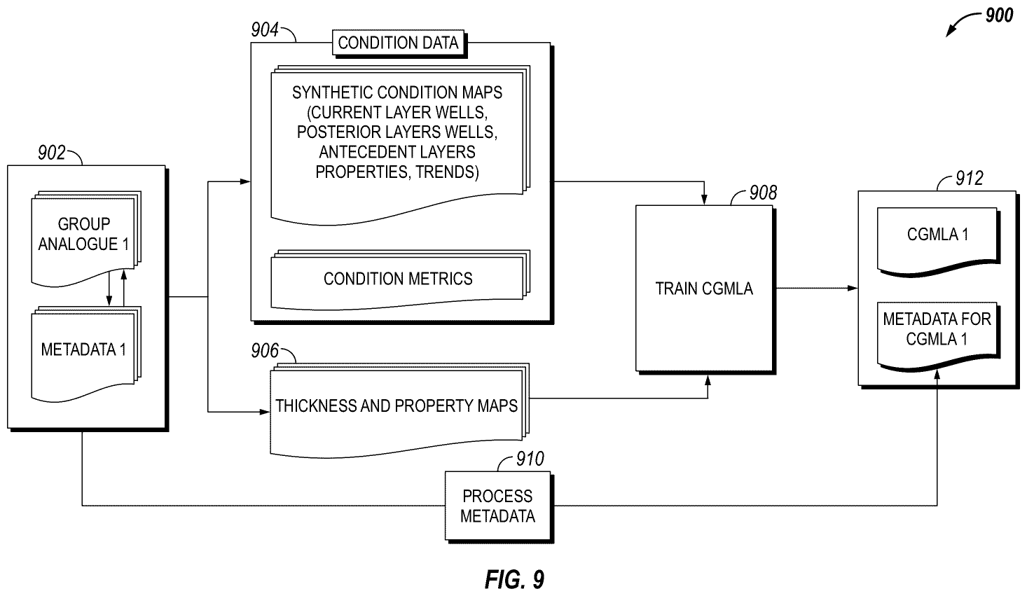

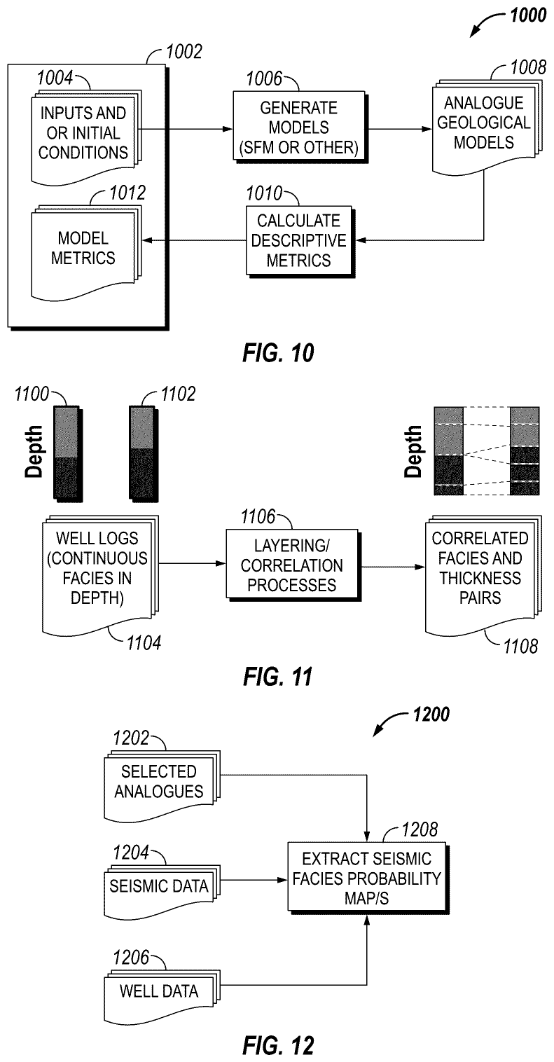

FIG. 9 illustrates training workflow 900 for forming one or more CGMLA models, in accordance with one or more embodiments of the present disclosure. In examples, training workflow 900 may be performed on information handling system 120. In block 902, analogue group 1 and metadata 1 may be selected from digital analogue library 1002. FIG. 10 illustrates a workflow 1000 that may be utilized to generate a digital analogue library 1002. Workflow 1000 may be at least in part performed on an information handling system 120 (e.g., referring to FIG. 1). Workflow 1000 may begin with block 1004. In block 1004, inputs and/or initial conditions for building a geologically realistic SFM are identified. Specifically, inputs may comprise, for example, an initial depositional surface, a sediment deposition rate value, or a direction of sediment transport. In block 1006 stratigraphic forward models (SFMs) and/or any other model may be formed from the inputs and initial conditions from block 1004. The models generated in block 1006 may be utilized as analogue geological models in block 1008. In block 1010, descriptive metrics may be calculated from analogue geological models of block 1008 to form the model metrics 1012. Blocks 1002 and/or 1004 may contain, e.g., store, metadata associated with each analogue model, which is a descriptor of block 1008. The metadata may later be used to parse through, differentiate between, match to, identify, or otherwise call one or more select digital analogues from the digital analogue library 1002.

Referring back to FIG. 9, in block 904 condition data comprises condition metrics and/or synthetic condition maps. Condition metrics may be values, classes, or labels used to condition a CGMLA. Condition metrics may be comprised within Metadata 1 from block 902. In examples, synthetic conditions may be formed from current well layers, posterior layer wells, antecedent layer properties, and/or other condition data trends. Data utilized in block 904 may be synthetic. For example, FIG. 11 illustrates an initial condition that may be utilized in block 904. Well conditioning may be utilized as an initial condition. As illustrated in FIG. 11, a first wellbore 1100 and a second wellbore 1102 may be formed in or around each other form drilling operations. Well logs 1104 for each wellbore 1100, 1102 may be utilized to determine continuous facies at any depth within wellbore 1100, 1102. In block 1106, layering/correlation processes may be performed by information handling system 120 to determine time-equivalent thickness and facies pairs between wellbores 1100, 1102. Block 1106 may utilize methods such as detailed manual correlation, dynamic-time warping type approaches, classic layering methods (proportional, conformable), and/or the like to correlated facies and thickness pairs. The correlation may be an illustrated output 1108 that may be viewable on information handling system 120. Other inputs and initial conditions may be utilized in conjunction with the correlated facies and thickness pairs found in FIG. 11.

Additionally, trend maps may be formed from selected analogues, seismic data, and well logs. For example, FIG. 12 illustrates a workflow 1200 for extracting a seismic facies probability map. This workflow may be performed on information handling system 120. As illustrated, selected analogues from block 1202, seismic data from block 1204, and well logs 1206 from Group Analogue 1 and/or Metadata 1 may be combined by to form extracted seismic facies probability maps in block 1208. Selected analogues from block 1202, seismic data from block 1204, and well logs 1206 may be combined by ML algorithms for predicting the presence of different facies in seismic data.

In block 906, thickness and property maps may be identified from Group Analogue 1 and/or Metadata 1. In examples thickness and property maps may be multi-dimensional data representations of thickness and/or property maps of a formation. In block 908 a conditional generative machine learning algorithm 1 (CGMLA) may be trained. To train CGMLA 1 a single synthetic condition map or layer from block 908 may be at least partially replicated. Current well layers, antecedent layer properties may be inputs required to be replicated. In contrast, other inputs from block 904 may be indirect conditions of the output but are not the feature(s) that need to be replicated. Thickness and property maps from block 906 may be further implemented to train CGMLA 1. The actions used to replicate the single synthetic condition map or layer are significant training parameters. These training parameters may be saved and/or compiled through multiple iterations to produce a trained CGMLA.

In block 910 metadata may be processed to form processed metadata. In examples processing metadata may comprise information lacking from Metadata 1 from block 902. For example, if several group analogues from block 902 comprise different input parameters, these inputs may be used to process a mean, median, or range of processed metadata. In block 912, the trained CGMLA 1 from block 908 and processed metadata from block 910 may be stored.

FIG. 10 is a workflow utilized to generate a digital analogue library 1002, in accordance with one or more embodiments of the present disclosure. Digital analogue library 1002 comprises a plurality of digital analogues as well as associated metadata. In examples, each digital analogue comprises (e.g., is derived from) an SFM. Each SFM may be associated with a specific depositional environment or geological concept. Beginning in block 1002, inputs and/or initial conditions are provided, which are used to generate the SFM models in block 1006. Block 1008 shows the output of performing one or more simulations of geological processes by implementing block 1006 on block 1004. In block 1010, descriptive metrics of the analogues are calculated to form model metrics 1012. These model metrics 1012 comprise indicators or other data specific to (e.g., correlated to) and descriptive of each digital analogue, for example, specific to the inputs/initial conditions 1004 and/or the generated SFM. In block 1012, the model metrics are linked to the digital analogues so that each digital analogue is identifiable by its corresponding descriptive metrics. The inputs and/or initial conditions of block 1004, as well as the model metrics may also be stored in the library with the digital analogues, or otherwise linked to the digital analogues without being stored in the digital analogue library in any suitable fashion such that the digital analogues are identifiable by the model metrics, inputs, and/or initial conditions.

FIG. 11 is a workflow for performing a layering process, in accordance with one or more embodiments of the present disclosure. The workflow of FIG. 11 may be used to obtain input conditions (e.g., for from real well data. In block 1104, well log data (or alternatively, well control data) is provided. This well log data is layered/correlated in block 1106, such that the identities of the different geological properties are identified at the various depths. This allows the facies to be correlated to a thickness, which may be used to determine the thickness distributions of each facies throughout the subsurface region.

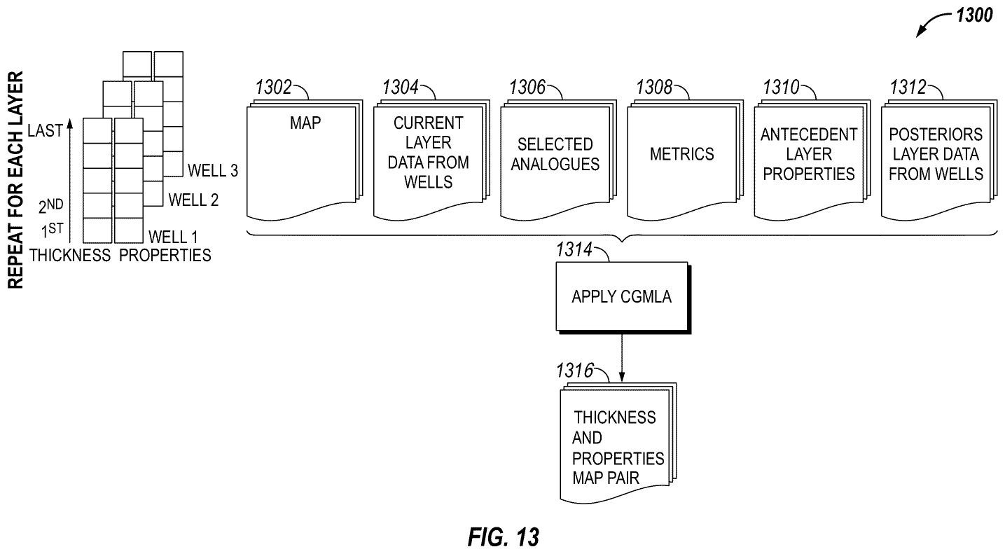

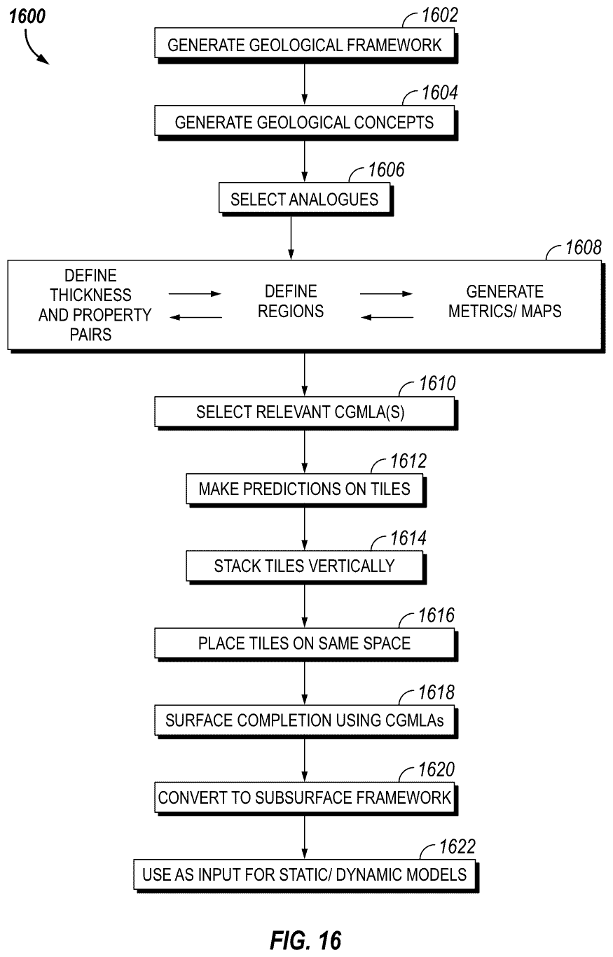

FIG. 12 is a workflow for extracting a seismic facies probability map, in accordance with one or more embodiments of the present disclosure. Beginning in block 1202, analogues from the digital analogue library 1002 (e.g., referring to FIG. 10) are selected. Selection of a particular set of analogues may be performed based on matching of the model metrics (e.g., block 1012 of FIG. 10) to observed or calculated parameters (e.g., geological concepts) of a subsurface geology. Seismic data and well log data are also provided in block 1204 and 1206. As mentioned previously, well log data may be substituted with or replaced by well control data. Based on the seismic data, well log data, and selected analogues, one or more facies probability maps may be generated, i.e., extracted in block 1208. In one or more examples, the probability maps may comprise nominal guesses of the placement of the facies within a geological framework or may comprise actual calculated probabilities. Compared to the final output of one or more workflows described herein, (e.g., workflow 1300 or workflow 1600 of FIGS. 13 and 16), the probability maps may represent the subsurface geology at a comparatively lesser degree of confidence and/or resolution. These calculated probabilities may be used in later workflows to inform future operations, for example, further selection of analogues, selection of one or more ensembles of machine learning models (e.g., GANs), and/or be used as input data to a trained CGMLA.

FIG. 13 illustrates application workflow 1300 for applying one or more trained CGMLAs to one or more input datasets to form output, in accordance with one or more embodiments of the present disclosure. In examples, application workflow 1300 may be performed on information handling system 120. As discussed, the CGMLA used to perform the operations of block 1314 may have been trained by information handling system 120 in accordance with the teachings provided herein, for example, according to FIG. 9. Training workflow 900 may be repeated from multiple groups selected from analogue model 1002 (e.g., referring to FIG. 9). As illustrated, the one or more datasets used as input to CGMLA in block 1314 may comprise, for example, datasets 1302, 1304, 1306, 1308, 1310, 1312 and any combination thereof, which are each discussed below.

Dataset 1302 may comprise one or more trend maps, such as one or more seismic facies probability maps. The one or more seismic facies probability maps may comprise the extracted facies probabilities determined, for example, in block 1208 (e.g., referring to FIG. 12). “Seismic facies probability maps,” as used herein, are maps, or three-dimensional datasets, detailing the probability of a particular type of facies being present within a given stratigraphic region of the formation. In one or more of the present examples, these probabilities are generated from previous seismic data using one or more machine learning and/or deep learning algorithms. In addition, the one or more seismic facies probability maps may comprise a plurality of maps over a period of time, such that the time-dependent and evolving nature of the facies may be captured, at least to some extent, by the dataset 1302. It should be understood that although this specific embodiment relies on facies probability maps derived from seismic data, other trend maps may be used to help guide the prediction and/or train machine learning model(s), as discussed throughout this disclosure. Alternative, or additional, trend maps may include, for example, coarser facies distribution maps derived from interpolations between wells, coarser geologic property maps from interpolation between wells, thickness maps derived from seismic data, maps based on sketches, combinations thereof, and the like.

Specific types of facies represented by dataset 1302 may include, to use non-limiting examples, various lithofacies (e.g., sandstone, mudstone, conglomerate, shale, siltstone, limestone, dolostone, chert, evaporite, coal, etc.), depositional facies (e.g., fluvial channel, deltaic, lacustrine, shallow or deep marine, alluvial fan, carbonate, etc.), sedimentological facies (e.g., cross-bedded sandstone, laminated mudstone, fluvial facies, deltaic facies, etc.), diagenetic facies (e.g., cemented sandstone, dolomitized limestone, silicified, stylolite, phosphatized, etc.), or any other suitable geological “type” of facies or geological concept, as used in that context. In one or more examples, information contained by dataset 1302 may relate to an amount of sand present within each stratigraphic region represented by the dataset. In essence, dataset 1302 may provide a basis for generally understanding the spatially-dependent properties of the formation prior to performing the more detailed rendering using the trained CGMLA.

Dataset 1304 may comprise data corresponding to one or more current layers of the one or more wells. As used herein, a “current layer” refers to the current k-layer being currently generated in an iterative process involving multiple k-layers, to be discussed later in detail. However, it should be understood that the specific steps for implementing the principles taught herein may be adapted to suit a particular application. In essence, however, knowledge about one or more surrounding stratigraphic regions and/or chronographic regions, for example, at the boundaries between two or more regions, may be used to inform a subsequent rendering of a new layer. For example, if a specific GAN or specific digital analogue was selected for a first layer, that selection may be accorded a higher probability of being selected in a second layer proximate the first layer. Likewise, if the rendering of a first layer resulted in a specific output, rendering of a second layer proximate (i.e., spatially, or chronologically) to the first layer may make use, at least in part, of that specific output, e.g., by using it as an input. In examples where rendering of a single layer relies on an iterative processes involving one or more initial guess (“nominal”) values, for example, data associated with a previously rendered layer may be used as the nominal value(s). Use in this manner may allow rendering of a final three dimensional output to be performed more quickly and with less error than if each layer was generated from blind (e.g., random) data, or if the entire three-dimensional space was rendered simultaneously. Non-limiting and exemplary examples of data to be used in dataset 1304 includes net-to-gross data, metadata of a digital analogue or GAN, channel weights in a neural network, other data associated with the one or more properties of a geospatial region, any combination thereof, or the like.

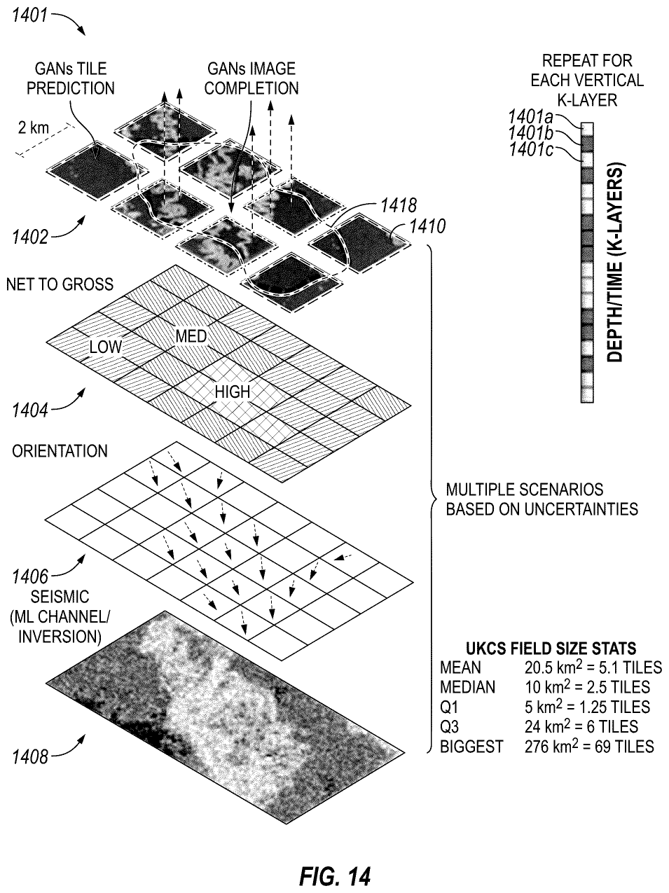

Dataset 1306 may comprise selected analogues from a digital analogue library 1002 (e.g., referring to FIG. 10). As mentioned, digital analogue library 1002 may comprise a plurality of digital analogues, each digital analogue representative of one or more separate models, (e.g., SFM model(s)), each digital analogue tuned to a specific type (or combination of types) of a stratigraphic region or geological concept. A particular digital dialogue of the library may be more appropriate for a given k-layer (or subdivided portion thereof, e.g., tile 1410 of FIG. 14) than another digital analogue, and so selection of the digital analogue(s) may be based on various region-specific factor(s). These region-specific factor(s) may include, to use a non-limiting example, data derived from analysis of one or more wells. Well analysis may be informed by any measurement tools commonly used in the oil and gas industry, such as various wireline logging tools (e.g., gamma ray log, acoustic log, resistivity log, porosity log, electrical potential log, etc.), as well as mud logs, measurement while drilling (MWD) and logging while drilling (LWD) logs, pressure and/or temperature gauges, production logging tools, cased hole logging tools, visual sensors (e.g., downhole cameras), downhole or surface fluid sampling tools, pressure transients, results from well tests, combinations thereof, or the like. Alternatively, or additionally, selection of the digital analogue(s) from the digital analogue library 1002 may be based on seismic data, such as data comprising or derived from one or more seismic sensors disposed in the one or more wells or at the surface, for example. Selection of analogues may alternatively, or additionally, be based on other aspects of geological evolution of a region of formation, such as the time-dependent, evolving characteristics of one or more geobodies. Alternatively, or additionally, the selection may be based on other contextual geological information such as position in a continental or marine basin, paleo-climate (e.g., dry-humid climate can affect sediment deposition), or the like. “Selection” of one or more SFMs from digital analogue library 1002 may refer to selection of one or more SFM-based digital analogues rather than selection of an actual SFM. One advantage of using dataset 1306 in the manner described is that it allows, in some examples, comparison(s) between known or estimated formation properties with the digital analogue metadata of the various digital analogues to inform the selection process. The selected analogues may thus be selected from the digital analogue library 1002 (e.g., referring to FIG. 10) and may thus comprise one or more of the models generated in block 1006.

Dataset 1308 may comprise metrics. Metrics may include, for example, the model metrics determined in block 1012 (e.g., referring to FIG. 10). These metrics are values, classes, labels, or identifiers which are used to condition the CGMLA. In one example, a model metric may comprise or be otherwise associated with net-to-gross (NTG) data. Alternatively, or additionally, data relating to facies proportions, e.g., ratios of one type of facies to another type of facies within a specified region of the formation. The model metrics may control the abundance of facies generated by the CGMLA for a given region and may be based on, or derived in, some examples from the metadata of the selected digital analogue(s). It should be noted that the meaning of the word “condition” may vary depending on the context of its use. “Conditioning,” such as “conditioning the CGMLA” may refer in some contexts to (i) training the CGMLA with conditioning data which results in a trained model, or (ii) prompt or otherwise provide one or more constraints to a trained predictive model to guide one or more predictions.

Dataset 1310 may comprise antecedent layer properties. As will be discussed in greater detail, computation of a subsequent k-layer in an iterative process may be based at least in part on information rendered during computation of k-layer(s) positioned beneath, i.e., “antecedent” to the k-layer being currently being rendered. In alternative “top-down” rendering examples, an anteedent layer may refer to one or more k-layer(s) positioned above the current layer. “Properties” herein refers to any of the geological concepts or properties of a chronostratigraphic region as disclosed herein, for example, reservoir properties, thickness, deposition rate, elevation, paleobathymetry, facies, derivatives thereof, combinations thereof, or the like. As used herein, “thickness” refers to the physical thickness of one or more layers.

Likewise, dataset 1312 may comprise posterior layer properties. As will be also discussed later with more detail, computation of a subsequent k-layer may be based at least in part on information rendered from data overlaying (spatially and chronologically) the current layer, i.e., “posterior” to the k-layers which are currently being rendered. That is to say, properties of a posterior layer may be used in some examples to inform the rendering of the current layer. It should be understood that while antecedent and posterior layers may refer to the layer immediately prior or immediately beneath the current k-layer, respectively, these layers may also more generally refer to one or more previous layers located prior/below or posterior/above.

Furthermore, while the k-layers are generally described as being parallel to the earth's surface, the specific orientation of the k-layers may be parallel, orthogonal, or tilted to any suitable orientation relative to the surface. For example, k-layers may be tilted to better conform or align with one or more facie(s), geobodies(s), bed(s), channel(s), etc., which may result in faster and/or more accurate predictions in some examples.

The output 1316 of applying an individual CGMLA (e.g., from block 900) in block 1314 to the one or more datasets comprises one or more two-dimensional maps. Each of the one or more two-dimensional maps may comprise or be derived from, for example, each of the one or more k-layers, to be discussed later in detail. Specifically, one or more ensembles of CGMLAs may be selected (e.g., by a superordinate machine learning model trained using conditioning data) and used to form a plurality of k-layers which may then be stacked together (e.g., by the same superordinate machine learning model) to render a (or a plurality of) three- or four-dimensional map(s) of the subsurface geology. Each map may comprise (or be derived from) information corresponding to thickness of a particular facie present within a chronostratigraphic section over time. In one example, the output 1316 represents one or more thickness and facies map pairs, such that both the identity of the individual facie(s) as well as its/their corresponding thickness(es) are represented. In another example, map(s) rendered from application workflow 1300 illustrate the three- and/or four-dimensional geospatial properties of a formation.

The one or more datasets input into the CGMLA at block 1314 may comprise data associated with or derived from a single well, a plurality of wells, and/or one or more spatial regions between one or more wells. In addition, any or all of the datasets described with reference to FIG. 13 may be individually or collectively used as input to CGMLA of 1314

FIG. 14 illustrates various two-dimensional maps for a single two-dimensional chronostratigraphic section corresponding to a defined time point (or interval) as predicted using application workflow 1300 (e.g., referring to FIG. 13) in accordance with one or more examples of the present disclosure. Predictions may comprise, to use non-limiting examples, facies thicknesses and/or distributions, net to gross, and other key parameters as described throughout this disclosure. One or more k-layers 1401a, 1401b, 1401c may be generated using information handling system 120 using, for example, application workflow 1300 (e.g., referring to FIG. 13). In one or more examples, the k-layers 1401a, 1401b, 1401c are generated using a superordinate machine learning model comprising one or more ensembles of selected subordinate generative machine learning models (e.g., GANs).

As illustrated, a single k-layer 1401 (e.g., one of k-layers 1401a, 1401b, 1401c) may comprise one or more separately rendered layers 1402, 1404, 1406, and 1408. The separately rendered layers (1402, 1404, 1406, 1408) may each represent a specific property of the formation which may be used to inform (or be used as) a k-layer 1401. The operations of workflow 1300 are iteratively performed at a plurality of depths and/or times, and the ensuing k-layers 1401a, 1401b, 1401c are later stacked together to produce a representation of the subsurface geology (e.g., a two- or three-dimensional graphical visualization).

Non-limiting examples of the specific properties captured by a k-layer 1401 may comprise, for example, porosity, permeability, facies, channel orientation, net-to-gross ratio, fluid flow, pressure gradient, temperature, and any combinations thereof.

As mentioned, generating multiple k-layers 1401a, 1401b, 1401c is an iterative process, meaning that one or more steps of application workflow 1300 are repeated for a plurality of depths and/or times. Generation of k-layer 1401b with application workflow 1300 may, in some examples, rely on one or more previously rendered k-layers, for example, 1401a. Likewise, generation of k-layer 1401c may rely on previous rendering of k-layers 1401a, 1401b. In this way, modeling of the subsurface geology is both more accurate and more computationally efficient than if the whole three-dimensional space was predicted simultaneously.

Generating of the various k-layers 1401a, 1401b, 1401c may be performed “bottom-up,” “top-down,” “older-to-younger,” “younger-to-older,” or any geologically feasible combination thereof. One potential advantage of an “older-to-younger” approach is that because some spatial properties (e.g., sediment deposition) are often influenced by pre-existing conditions, subsequently generated k-layers may benefit from the known properties of those pre-existing conditions. Accordingly, in some examples, a k-layer generator may be configured such that subsequent k-layers are generated in both a bottom-up and an older-to-younger fashion.

As shown in the example of FIG. 14, a k-layer 1401 and/or separately rendered layer 1402, 1404, 1406, and 1408 may each comprise a plurality of tiles 410, i.e., subdivisions. Alternatively, these layers may each comprise a single uniform two-dimensional layer. Each tile 1410 is a two-dimensional quadrant spanning an area of about 4 square kilometers. The amount of area covered by a single tile 1410 may vary depending on a variety of factors, for example, the desired quality or resolution of the subsurface modeling at a specific region or timespan, availability of computation power, desired computational efficiency, the size and/or scale of training data (e.g., two-dimensional images) used to train the CGMLA, or the like. For example, each tile 1410 may span an area from about 0.1 square kilometers to about 10 square kilometers, or any ranges therebetween. Spatial properties for each subregion represented by a tile 1410 of k-layers 1401a, 1401b, 1401c may be predicted using, for example, a GAN specific to that individual tile 1410. In such examples, selection of a specific GAN for a specific tile 1410 may be based on observed, extrapolated, and/or predicted spatial properties of the formation at one or more edges of a neighboring tile.

As used herein, “well control” refers to the continuous monitoring and controlling of one or more formation-specific parameters, e.g., hydrostatic pressure, of a particular region of a subterranean formation in the general proximity of a wellbore by using one or more wellbore techniques, e.g., mud pumps, frac pumps, blowout preventers, etc. In one or more examples, well control data may be used as conditioning data for conditioning the CGMLA, for example, in addition to or substitution for dataset 1304 (e.g., referring to FIG. 13). In one or more examples, well control data may be used to control the result of the CGMLA.

In the illustrated example, some of the tiles represent areas of the formation where well control is present, and some of the tiles represent areas of the formation where well control is not present. Subdivision of the k-layers 1401a, 1401b, 1401c into tiles allows for a rendering of the geological properties of the formation more precisely and with greater granularity, as well as with greater computational efficiency. Specifically, in one or more examples, individual trained CGMLAs may be assigned to each tile.

In the example shown, boundary 1418 is represented by a dotted line to show an oil field. Boundary 1418 may encompass target reservoir rock as well as non-target reservoir rock. Boundary 1418 may inform the selection of a trained CGMLA to be used for each tile 1410.

As mentioned, each k-layer 1401 may contain information about net-to-gross (NTG) ratio of one or more subregions of the one or more chronostratigraphic regions. NTG ratio is the ratio of the volume of a target reservoir rock (e.g., “pay zone”) to the total volume of a particular subregion. The total volume of a subregion may include, for example, reservoir rock as well as non-reservoir rock. Characterization of NTG ratio may be numerical (e.g., between 0 and 1), or more generally characterized, such as with one or more indicators, e.g., “low,” “medium,” or “high”. Generating the one or more k-layers 1401a, 1401b, 1401c and/or subdivided portions thereof may ensure, in some examples, high accuracy of NTG ratio prediction.

As mentioned, k-layers 1401a, 1401b, 1401c may contain information about channel orientation. “Channel orientation”, as used herein, refers to the local directional alignment (e.g., “trend”) of one or more geological channels found in sedimentary rocks or a depositional environment. In one or more examples, channel orientation may be used to describe the direction of a river, stream, submarine channel, or other fluid flow path within the one or more chronostratigraphic regions. Information about channel orientation is useful in that it may be used to inform subsequently generated k-layers 1401a, 1401b, 1401c, which may enhance the quality of the subsurface geological model. The subsurface geological model formed in FIG. 14 may further be illustrated in a layer-by-layer rendering.

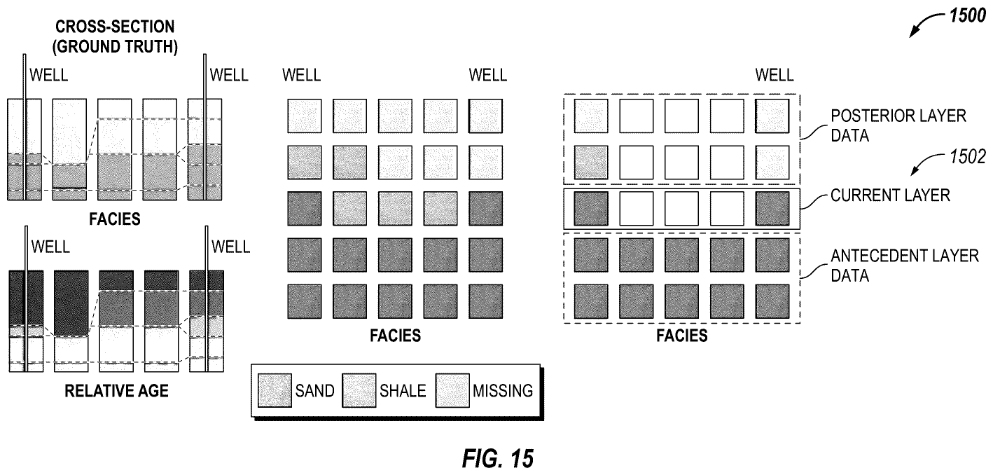

FIG. 15 illustrates a layer-by-layer rendering of a subsurface geological model comprising a plurality of k-layers. As illustrated, current layer 1502 is a two-dimensional layer (e.g., k-layers 1401a, 1401b, 1401c, referring to FIG. 14) being rendered to be stacked with other rendered layers to form a subsurface geological model representing the spatial properties of a subterranean formation.

As illustrated, the one or more chronostratigraphic sections 1500 may be rendered layer-by-layer. As mentioned, rendering of subsequent layers may be informed by previously rendered layers and/or pre-existing information. Previously rendered layers may encompass, for example, older regions (e.g., relative age) and/or regions of greater depth relative to current layer 1502. Pre-existing information may include, for example, data from one or more well logs, seismic data, or other sources of data corresponding to the properties of the subterranean formation. Pre-existing information is used, for example, during first rendering of an initial layer where no antecedent or posterior layer is available, or where only the pre-existing information is available.

Identification of the various types of facies captured by the rendered layers may be performed, for example, in accordance with block 1106 (e.g., referring to FIG. 11). Use in this manner allows the thickness of a particular facies over a given two-dimensional region to be precisely determined. In addition, it allows in some examples for previously unidentified regions of a formation to be properly characterized.

FIG. 16 is a workflow 1600 for modeling a subsurface geology using a plurality of digital analogues and a plurality of trained CGMLAs, in accordance with one or more embodiments of the present disclosure. As with other the other figures, workflow 1600 may be performed using information handling system 120. Beginning in block 1602, a geological framework is generated. This may include generating of a low resolution multidimensional (e.g., three- or four-dimensional) model of the formation. In block 1604, a plurality of geological concepts is generated. These geological concepts are based on the generated geological framework and may include a preliminary estimating of any of the geological properties described herein. In block 1606, based on the generated geological framework and geological concepts, a plurality of digital analogues is selected (e.g., from digital analogue library 1002). Each analogue of the selected plurality may correspond to (e.g., be associated with), for example, a particular depositional environment. In block 1608, the identities and thicknesses of various facies are defined, a plurality of regions are defined, and trend maps (e.g., trend maps generated in FIG. 12) and metrics are generated. The operations of block 1608 are performed, at least in part, using the selected plurality of analogues. Moreover, any of the operations of block 1608 may be interdependent. For example, the operation of defining regions may be based on the defining of the thickness and facies, or vice versa.

In block 1610, based on some or all of the information determined in block 1608, a plurality of trained CGMLAs is selected (e.g., from a library of trained CGMLAs) to form one or more ensembles. In one or more examples, each trained CGMLAs of an ensemble corresponds to (e.g., is associated with) a particular depositional environment, or more generally, a type of region (e.g., the regions defined in block 1608 or subregion(s) thereof). Alternatively, or additionally, each of the trained CGMLAs are each selected based on a matching of their metadata to metadata of each of the selected plurality of analogues at its corresponding k-layer and/or subdivided portion thereof. The one or more ensembles of trained CGMLAs may be matched according to features or geological concepts of a given k-layer, boundary, or subdivision(s) thereof. Selection of and/or matching of metadata and features may be performed by an additional machine learning model, which may be separate and superordinate with respect to the one or more ensembles. Moreover, the additional machine learning model may have been trained on conditioning data to, among other things, (i) optimally perform the selection process of the one or more ensembles and/or (ii) select computational parameters associated with the operations performed by the digital analogues and/or trained CGMLAs. In addition, such additional machine learning model may be used in some examples to perform subsequent blocks (e.g., any of blocks 1612-1622) of workflow 1600.

While the various blocks of workflow 1600 are presented and described sequentially, one of ordinary skill in the relevant art (having the benefit of this detailed description) would appreciate that some or all steps may be executed in different orders, combined, or omitted, and some or all steps may be executed in parallel. In block 1612, predictions are generated for a plurality of tiles. This may involve, for example, assigning one (or more) trained CGMLAs from the selected plurality of block 1608 to each tile and generating output using the assigned trained CGMLA(s). In block 1614, tiles are stacked vertically. In block 1616, tiles are placed on the same space. In block 1618, the selected trained CGMLAs are used to perform a surface completion. In block 1620, the surface completion is converted to a subsurface framework. In block 1622, the subsurface framework of block 1620 may be optionally used as input for static and/or dynamic models.

The workflows (e.g., workflow 1600) of the present disclosure may, in one or more examples, be configured to: use GANs to generate the nonstationary, realistic geological models of the present disclosure, trained using training images including those from SFM(s); condition a model using well/seismic data; use stratigraphic sketches depicting distribution of lithologies, rock types, and facies to condition a model; use distance transformation that measures mismatch between the generated samples by GANs and the conditioning data (e.g., facies observations in well locations); use one or more geological concepts to inform the GAN(s); quantify uncertainty of anticipated reservoir performance; employ a time series approach (e.g., whereby data from one point in time is used to inform data generated at a later point in time); and any combinations thereof.

Specific improvements of the present disclosure may include, in some examples: the ability to define vertical proportion curves and apply different generative machine learning models (e.g., GANs) vertically/spatially; determine thickness such that it is not necessary to train three-dimensional GANs which is allied with employing a time series approach whereby data from one point in time is used to inform data generated at a later point in time; use machine learning derived geological insights/concepts (e.g., probability maps of channel likelihood and/or facies probabilities derived from seismic data); use one or more paleo-digital elevation models and or environmental sequence stratigraphy to condition GAN; analyze existing well data to determine which trained GAN models are most suitable to use; resolve uncertainties (e.g., between different well correlations, lithofacies, seismic interpretations, etc.) as well as any stochastic variations, generate ensembles of models that allow true assessment of uncertainty; and create tiles around well control, whereby the edges of the tiles become constraining data for subsequent tiles, thereby allowing coherent scaling of a GAN's predictions.

The systems and methods may include any of the various features disclosed herein, including one or more of the following statements.

Statement 1: A method comprising: selecting one or more stratigraphic forward models from a digital analogue library; generating one or more k-layers based at least in part on the one or more selected stratigraphic forward models and one or more generative machine learning models; and predicting thicknesses of one or more geological properties based at least in part on the one or more k-layers.

Statement 2: The method of statement 1, wherein each of the one or more stratigraphic forward models is associated with a depositional environment.

Statement 3: The method of statements 1 or 2, further comprising: selecting one or more ensembles of generative machine learning models from a directory comprising the one or more generative machine learning models; assigning each generative machine learning model of the one or more ensembles to one or more k-layers and/or subdivided portions thereof, guiding one or more predictions of the one or more generative machine learning models with the selected stratigraphic forward models; and performing one or more wellbore operations based at least in part on the predicted thicknesses of the one or more geological properties.

Statement 4: The method of statement 3, wherein the generative machine learning models comprise one or more generative adversarial networks.

Statement 5: The method of statement 3, further comprising quantifying at least an uncertainty of an anticipated reservoir performance based at least in part on the one or more guided predictions.

Statement 6: The method of statement 3, wherein selecting the one or more ensembles is performed by a superordinate machine learning model.

Statement 7: The method of statement 6, further comprising stacking the one or more k-layers to model a subsurface geology.

Statement 8: The method of statement 7, further comprising training a machine learning algorithm with conditioning data to form the superordinate machine learning model, wherein modeling the subsurface geology is performed by the superordinate machine learning model.

Statement 9: The method of any of statements 1-8, further comprising training one or more generative machine learning algorithms to form the one or more generative machine learning models using conditioning data.

Statement 10: The method of any of statements 1-9, wherein each k-layer comprises a plurality of tiles, wherein edges of the plurality of tiles are used as constraining data for generating of subsequent tiles.

Statement 11: The method of any of statements 1-10, wherein generating at least one of the one or more k-layers is based at least in part on one or more previously generated k-layers.

Statement 12: The method of any of statements 1-11, further comprising: performing a surface completion based at least in part on the one or more k-layers; and converting the surface completion to a subsurface framework.

Statement 13: The method of statement 12, further comprising using the subsurface framework as input to at least a static or a dynamic model.

Statement 14: The method of any of statements 1-13, further comprising matching geological concepts to metadata of the one or more stratigraphic forward models, wherein the selecting of the one or more stratigraphic forward models is performed based at least in part on the matching.

Statement 15: The method of statement 14, wherein the metadata comprises one or more identifiers associated with at least one geological parameter selected from the group consisting of net to gross, channel orientation, sediment deposition rate, facies probability, and any combination thereof.

Statement 16: The method of statement 15, wherein the generating of the one or more k-layers is performed for a plurality of time points within a time frame, wherein the predicted thicknesses of the one or more facies accounts for sediment deposition over a depositional time period.

Statement 17: A method comprising: selecting one or more digital analogues from a digital analogue library comprising a plurality of digital analogues, each digital analogue based on one or more geological models, each geological model associated with a depositional environment; conditioning a plurality of machine learning algorithms to form a plurality of conditioned generative machine learning models; predicting one or more thickness distributions of one or more facies with the plurality of conditioned generative machine learning models based at least in part on the selected digital analogues; and performing one or more wellbore operations based at least in part on the one or more predicted thickness distributions.

Statement 18: The method of statement 17, further comprising: mapping probabilities of one or more geological properties of a geological column; and selecting one or more ensembles of the conditional generative machine learning models from a directory of the conditioned generative machine learning models, wherein the selecting is based at least in part on a matching of the mapped probabilities to metadata of the one or more conditional generative machine learning models.

Statement 19: The method of statement 18, wherein the one or more predicted thickness distributions account for sediment deposition over a deposition period, and wherein the metadata comprises one or more identifiers associated with a depositional environment.

Statement 20: The method of any of statements 17-19, further comprising: mapping probabilities of an average, minimum, or maximum value of one or more geological properties; and determining proportions of rock lithologies.

Although the present disclosure and its advantages have been described in detail, it should be understood that various changes, substitutions, and alterations may be made herein without departing from the spirit and scope of the disclosure as defined by the appended claims. The preceding description provides various examples of the systems and methods of use disclosed herein which may contain different method steps and alternative combinations of components. It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the element that it introduces.

For the sake of brevity, only certain ranges are explicitly disclosed herein. However, ranges from any lower limit may be combined with any upper limit to recite a range not explicitly recited, as well as ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method comprising:
selecting one or more stratigraphic forward models from a digital analogue library;
generating one or more k-layers based at least in part on the one or more selected stratigraphic forward models and one or more generative machine learning models; and
predicting thicknesses of one or more geological properties based at least in part on the one or more k-layers.

2. The method of claim 1, wherein each of the one or more stratigraphic forward models is associated with a depositional environment.

3. The method of claim 1, further comprising:
selecting one or more ensembles of generative machine learning models from a directory comprising the one or more generative machine learning models;
assigning each generative machine learning model of the one or more ensembles to one or more k-layers and/or subdivided portions thereof,
guiding one or more predictions of the one or more generative machine learning models with the selected stratigraphic forward models; and
performing one or more wellbore operations based at least in part on the predicted thicknesses of the one or more geological properties.

4. The method of claim 3, wherein the generative machine learning models comprise one or more generative adversarial networks.

5. The method of claim 3, further comprising quantifying at least an uncertainty of an anticipated reservoir performance based at least in part on the one or more guided predictions.

6. The method of claim 3, wherein selecting the one or more ensembles is performed by a superordinate machine learning model.

7. The method of claim 6, further comprising stacking the one or more k-layers to model a subsurface geology.

8. The method of claim 7, further comprising training a machine learning algorithm with conditioning data to form the superordinate machine learning model, wherein modeling the subsurface geology is performed by the superordinate machine learning model.

9. The method of claim 1, further comprising training one or more generative machine learning algorithms to form the one or more generative machine learning models using conditioning data.

10. The method of claim 1, wherein each k-layer comprises a plurality of tiles, wherein edges of the plurality of tiles are used as constraining data for generating of subsequent tiles.

11. The method of claim 1, wherein generating at least one of the one or more k-layers is based at least in part on one or more previously generated k-layers.

12. The method of claim 1, further comprising:
performing a surface completion based at least in part on the one or more k-layers; and
converting the surface completion to a subsurface framework.

13. The method of claim 12, further comprising using the subsurface framework as input to at least a static or a dynamic model.

14. The method of claim 1, further comprising matching geological concepts to metadata of the one or more stratigraphic forward models, wherein the selecting of the one or more stratigraphic forward models is performed based at least in part on the matching.

15. The method of claim 14, wherein the metadata comprises one or more identifiers associated with at least one geological parameter selected from the group consisting of net to gross, channel orientation, sediment deposition rate, facies probability, and any combination thereof.

16. The method of claim 15, wherein the generating of the one or more k-layers is performed for a plurality of time points within a time frame, wherein the predicted thicknesses of the one or more facies accounts for sediment deposition over a depositional time period.

17. A method comprising:
selecting one or more digital analogues from a digital analogue library comprising a plurality of digital analogues, each digital analogue based on one or more geological models, each geological model associated with a depositional environment;
conditioning a plurality of machine learning algorithms to form a plurality of conditioned generative machine learning models;
predicting one or more thickness distributions of one or more facies with the plurality of conditioned generative machine learning models based at least in part on the selected digital analogues; and
performing one or more wellbore operations based at least in part on the one or more predicted thickness distributions.

18. The method of claim 17, further comprising:
mapping probabilities of one or more geological properties of a geological column; and
selecting one or more ensembles of the conditional generative machine learning models from a directory of the conditioned generative machine learning models, wherein the selecting is based at least in part on a matching of the mapped probabilities to metadata of the one or more conditional generative machine learning models.

19. The method of claim 18, wherein the one or more predicted thickness distributions account for sediment deposition over a deposition period, and wherein the metadata comprises one or more identifiers associated with a depositional environment.

20. The method of claim 17, further comprising:
mapping probabilities of an average, minimum, or maximum value of one or more geological properties; and
determining proportions of rock lithologies.
